(19) United States
(12) Patent Application Publication
(10) Pub. No.: US 2023/0204621 A1
(43) Pub. Date: Jun. 29, 2023

(54) MODE LOCALISED ACCELEROMETER

(71) Applicant: Cambridge Enterprise Limited, Cambridge (GB)

(72) Inventors: Ashwin SESHIA, Cambridge (GB); Chun ZHAO, Cambridge (GB); Milind PANDIT, Cambridge (GB)

(21) Appl. No.: 17/926,915

(22) PCT Filed: May 18, 2021
(86) PCT No.: PCT/GB2021/051198

§ 371 Date: Nov. 21, 2022

(30) Foreign Application Priority Data
May 21, 2020 (GB) 2007592.5

(51) Int. Cl. G01P 15/097; G01P 15/13

(52) U.S. Cl. CPC G01P 15/097; G01P 15/13; G01P 2015/0814

(57) ABSTRACT

An accelerometer comprising: a frame; one or more proof masses suspended from the frame by one or more flexures and movable relative to the frame along a sensing axis; a resonant element assembly, the resonant element assembly comprising a first resonant element and a second resonant element coupled to one another, the first resonant element connected between the one or more proof masses and the frame, the second resonant element connected between the one or more proof masses and the frame, such that movement of the one or more proof masses relative to the frame along the sensing axis results in one of the first and second resonant elements undergoing compression and the other of the first and second resonant elements undergoing tension; and drive circuitry configured to drive the resonant element assembly and a sensing circuit configured to determine a measure of acceleration.

### RELATED APPLICATIONS

This application is a U.S. national phase application, claiming priority under 35 U.S.C. § 371 to PCT application PCT/GB2021/051196, filed on May 18, 2021, claiming priority to UK national application GB 2007379.7, filed on May 19, 2020, the contents of these applications incorporated by reference as if fully set forth herein in their entirety.

### FIELD OF THE INVENTION

The invention relates to accelerometers. In particular, the invention relates to accelerometer designs that are highly sensitive to small changes in acceleration and can be used as gravimeters.

### BACKGROUND TO THE INVENTION

A resonant sensor is an oscillator whose output resonant frequency is a function of an input measurand. In other words, the output of a resonant sensor corresponds to the shift in resonant frequency of a mechanical microstructure that gets tuned in accordance with a change in a physical quantity to be measured.

There has been an increased interest over the past few years in the development of high precision micromachined ‘all-silicon’ resonant micro-accelerometers. This interest has been triggered due to the recent growth in demand for miniature high precision motion sensors within the aerospace, automotive and even the consumer-electronics markets. Resonant micro-accelerometers fabricated using silicon micromachining techniques present a number of significant advantages, the biggest being economy. These silicon resonant micro-accelerometers not only boast improved sensitivity and resolution relative to their more traditional capacitive detection based counterparts with similar device footprints, but have also been shown to provide enhanced dynamic range making them ideal candidates for potential application in numerous motion sensing applications within the identified markets. One potential sensing application is gravimetry. Resonant accelerometers can be designed to provide a low-noise response for near-DC measurements (suitable for applications in gravimetry) and a wide dynamic range enabling measurements over the entire +/−1 g regime.

Accelerometer designs that exploit mode localization between two or more weakly coupled resonators have been proposed. The variations in the eigenstates (which refer to the relative amplitudes at the resonant frequencies measured from each of the resonators) due to induced strain modulation one of the resonators, yields a measure of the inertial force on the sensor. Measuring such eigenstate variations induced by mode localization offers two key advantages over conventional resonant frequency shift based measurements: insensitivity to unwanted environmental variations; and orders of magnitude enhancement in the output sensitivity and consequently, the resolution of such sensors.

It is an object of the present invention to provide a resonant accelerometer that provides the advantages of using mode localization but that has an improved scale factor when compared to previous designs.

### SUMMARY OF THE INVENTION

In a first aspect, there is provided an accelerometer comprising:

a frame;

one or more proof masses suspended from the frame by one or more flexures and movable relative to the frame along a sensing axis;

a resonant element assembly, the resonant element assembly comprising a first resonant element and a second resonant element coupled to one another, the first resonant element connected between the one or more proof masses and the frame, the second resonant element connected between the one or more proof masses and the frame, such that movement of the one or more proof masses relative to the frame along the sensing axis results in one of the first and second resonant elements undergoing compression and the other of the first and second resonant elements undergoing tension; and

drive circuitry configured to drive the resonant element assembly into one or more resonant modes and a sensing circuit configured to determine a measure of acceleration based on changes in resonant behaviour of the first and second resonant elements.

With this arrangement, because one resonant element undergoes compression while the other undergoes tension, a level of common mode rejection can be achieved using only a single pair of coupled resonant elements. This means that for a given size of accelerometer, the size, and hence mass, of the proof mass can greater than when two pair of resonant elements are used to provide a differential output. Further, when fabricating the accelerometer from a single piece of silicon, locating the resonant element assembly at the centre of the structure allows for better matching between the two resonant elements, improving common mode rejection.

Advantageously, the first resonant element extends from the frame towards the one or more proof masses along the sensing axis in a first direction and the second resonant element extends from the frame towards the one or more proof masses along the sensing axis in a second direction opposite to the first direction.

Advantageously, the first and second resonant elements are substantially identical. In embodiments in which the one or more proof masses comprise two proof masses, preferably the first resonant element is connected to a first proof mass and the second resonant element is coupled to a second proof mass. Preferably, the first and second proof masses have an identical mass.

In some embodiments, the one or more proof masses comprises a single proof mass and the first and second resonant elements are both coupled to the single proof mass. This arrangement provides for the potential to maximise the mass of the proof mass for a given size of sensor. In addition, the use of a single proof mass, reduces thermo-mechanical noise compared to multiple proof masses. In these embodiments, advantageously the first and second resonant elements are surrounded by the single proof mass. As explained, by placing the resonant elements in the centre of the structure, the resonant elements can be better matched in the fabrication process.

One or both of the first and second resonant elements may be connected to the one or more proof masses through a force amplifying lever. This may improve the scale factor of the acceleration measurement.

The first resonant element may be coupled to the second resonant element by a mechanical coupling. For example, the first resonant element may be coupled to the second resonant element by a coupling beam. The first resonant element, coupling beam and second resonant element may be integrally formed from a single material, such as silicon.

The coupling beam may be a serpentine beam. A serpentine shape for the coupling beam may reduce the sensitivity of the sensor to temperature fluctuations. In particular, the strength of the coupling between the first and second resonant elements affects the resonant behaviour of the resonant element assembly. A serpentine beam provides a coupling strength that is less sensitive to temperature changes.

The first resonant element may be connected to the frame at a first anchor and the second resonant element may be connected to the frame at a second anchor. The sensor may be configured so that first and second resonant elements vibrate in a first mode of vibration or a second mode of vibration. The mechanical coupling may be connected to the first resonant element at or close to a nodal point of first resonant element in at least one mode of vibration. The mechanical coupling may be connected to the second resonant element at or close to a nodal point of the second resonant element in the at least one mode of vibration. By coupling at or close to a nodal point of vibration during operation, the coupling strength can be minimised. This leads to maximal mode localisation and so a maximum scale factor for the accelerometer. In this context, “close to a nodal point” means closer to a nodal point than to an adjacent anti-nodal point.

The first anchor may be coincident with the second anchor. In that case, the mechanical coupling may be a portion of the frame. This requires a non-ideal anchor. A perfect anchor would have zero displacement at all points of connection to a resonant element so that no energy can couple through it. In practice there is some displacement of the resonant elements at the anchors. By fabricating an anchor deliberately to allow some displacement, coupling can be achieved. This arrangement has the advantage that the first and second resonant beams can extend along the same sensing axis, without any offset. There is no need for a coupling beam. This may reduce temperature sensitivity of the sensor. However, it may be more difficult to obtain a consistent and controlled level of coupling using this approach when compared to the use of a coupling beam.

As an alternative to a mechanical coupling, or in addition to a mechanical coupling, the first and second resonant elements may be electrostatically coupled to one another.

In some embodiments, the resonant element assembly comprises a third resonant element coupled to one or both of the first and second resonant elements. The third resonant element may be coupled to the first resonant element, or the second resonant element, or both the first resonant element and the second resonant element. The coupling between the third resonant element and the first or second resonant element may be provided by a mechanical coupling, such as a serpentine beam, or by an electrostatic coupling, or both.

The third resonant element may have different mechanical properties to the first resonant element and the second resonant element. This may enhance the mode localisation that occurs when the sensor is subject to an acceleration, improving the sensitivity of the accelerometer. For example, the third resonant element may have a different stiffness to the first resonant element and the second resonant element. Any number of further coupled resonant elements may be included.

The drive circuitry is configured to drive the resonant element assembly into one or more resonant modes. When the one or more proof masses undergoes an acceleration along the sensing axis the first and second resonant elements experience different strain, changing the resonant behaviour of the resonant element assembly. In particular, the relative amplitude of vibration provides a measure of acceleration of the proof mass along the sensing axis. The drive circuitry may be configured to provide a drive signal to the first resonant element, the second resonant element, or both the first and second resonant elements.

The drive circuitry may be configured to provide a parametric pumping signal to the resonant element assembly. The parametric pumping signal may be used to compensate for any mismatch in the resonant frequencies of the first and second resent elements when they are unstrained. The frequency of the parametric pumping signal may be equal to a difference between a resonant frequency of the first resonant element and a resonant frequency of the second resonant element. The parametric pumping signal may be applied to one of the first resonant element and the second resonant element.

The sensing circuitry may be configured to provide an output based on the amplitudes of vibration of the first resonant element and the second resonant element. The accelerometer may operate by providing a ratio of the amplitudes of vibration of the first resonant element and the second resonant element. Advantageously, the drive and sensing circuitry is configured to maintain an amplitude of vibration of the first resonant element constant and the output of the accelerometer is based on the amplitude of vibration of the second resonant element. This configuration can enable a significant increase in sensitivity at the expensive of the dynamic range of measurement.

The accelerometer may be a micro electro mechanical systems (MEMS) device. The accelerometer may be fabricated from a semiconductor material, such as silicon. The frame, one or more proof masses and the resonant element assembly may be fabricated from a single piece of semiconductor material. The single piece of semiconductor material may be etched or machined to provide the one or more proof masses and the resonant element assembly.

The resonant elements may be single clamped-clamped beams. The resonant elements may be double ended tuning fork (DETF) beams.

In another aspect, there is provided a gravimeter comprising an accelerometer according to the first aspect.

In a further aspect, there is provided a borehole tool comprising one or more accelerometers in accordance with the first aspect.

### BRIEF DESCRIPTION OF THE DRAWINGS

Embodiments of the invention will now be described in detail, by way of example only, with reference to the accompanying drawings, in which:

FIG. 1 is a schematic illustration of a first embodiment of the invention;

FIG. 2 illustrates drive and sensing circuitry for use with the embodiment of FIG. 1;

FIG. 3 is a flow diagram of the control process for the circuitry of FIG. 2;

FIG. 4 is a schematic illustration of a second embodiment of the invention;

FIG. 5 is a schematic illustration of a third embodiment of the invention;

FIG. 6 is a schematic illustration of a fourth embodiment of the invention;

FIG. 7 is a schematic illustration of resonant elements that can be used; and

FIG. 8 is a schematic illustration of a borehole tool including an accelerometer.

### DETAILED DESCRIPTION

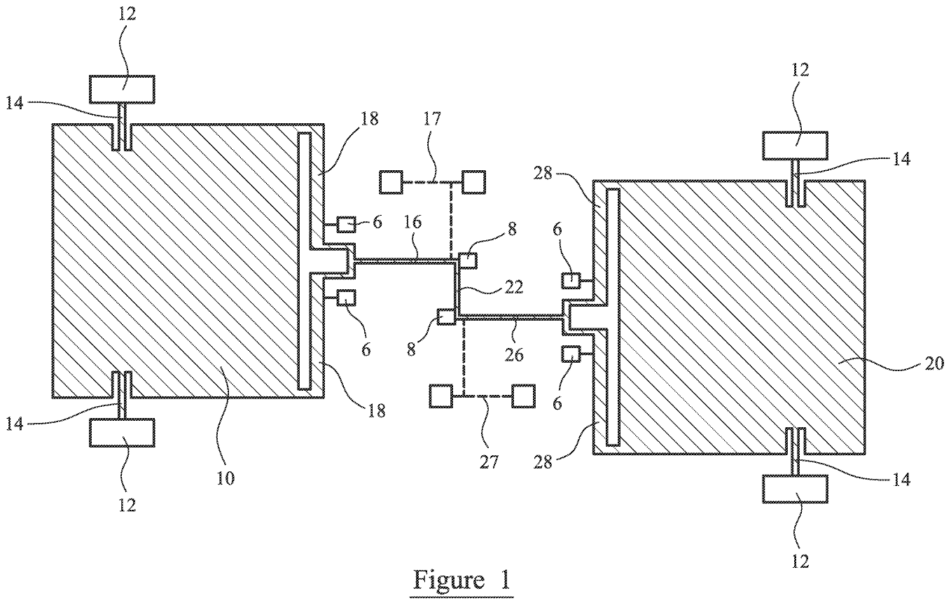

FIG. 1 is a schematic illustration of a top view of an accelerometer in accordance with the present invention. The accelerometer is advantageously fabricated entirely from a single semiconductor wafer, such as a silicon-on-insulator (SOI) wafer.

The accelerometer comprises a first proof mass 10 and a second proof mass 20. The first proof mass is suspended from a frame 12 by flexures 14 so as to allow movement of the first proof mass along an axis, towards and away from the second proof mass. The second proof mass 20 is suspended from the frame 12 by flexures 14 in the same way, so as to allow movement of the second proof mass along the same axis, towards and away from the first proof mass. The axis is the sensitive axis of the accelerometer.

A first resonant element 16 is connected between an anchor 8 and the first proof mass 10. The anchor 8 is part of the frame 12. The first resonant element extends along the sensitive axis.

The first resonant element 16 is connected to the first proof mass 10 through amplifying levers 18. The amplifying levers 18 are fixed to the frame at pivot points 6.

A second resonant element 26, identical to the first resonant element 16, is connected between a second anchor 8 and the second proof mass 20. The second proof mass is also identical to first proof mass, and the force amplifying levers 28 are identical to the force amplifying levers 18. The second resonant element extends along the same sensitive axis as the first resonant element, but in an opposite direction. This means that when the accelerometer undergoes an acceleration, the second resonant element 26 experiences an equal but opposite strain to the first resonant element 16.

The first and second resonant elements 16, 26 are coupled by a coupling beam 22. In this example the coupling beam 22 is a simple linear beam. The coupling beam is formed from the same silicon wafer as the resonant elements.

Energy can be transferred from one resonant element to the other through the coupling beam. When the resonant elements experience opposite strain to one another, and so have different resonant properties, energy can be localised more in one resonant element than the other. This phenomenon is often referred to as mode localisation.

The amount of mode localisation is dependent on the degree to which the strain on the first and second resonant elements is different. So the relative amplitude of vibration of the first and second resonant elements can be used to provide a measure of acceleration experienced by the proof masses. In fact, measuring amplitude variations induced by mode localisation provides a high resolution determination of acceleration that is relatively insensitive to environmental variation. This is described fully in WO2011/148137.

With the arrangement of FIG. 1, because one resonant element undergoes compression while the other undergoes tension, a level of common mode rejection can be achieved using only a single pair of coupled resonant elements. This means that for a given size of accelerometer, the size, and hence mass, of the proof mass can greater than when two pairs of resonant elements are used to provide a differential output. Furthermore, locating the resonant element assembly at the centre of the structure allows for better matching between the two resonant elements, improving common mode rejection.

The weaker the coupling between the resonant elements the more pronounced the mode localisation and so the high resolution the measurement. However, the weaker the coupling is between the resonant elements the closer the resonant modes are in frequency. The coupling must therefore be non-zero and sufficient for each resonant mode to be resolvable from each other. In other words the coupling must be strong enough that there is no modal overlap in the coupled response of the system. In order to ensure the structure is robust and can be consistently produced, the coupling beam needs to have sufficient thickness.

The coupling beam between the first and second resonant element is positioned close to the anchors 8. Positioning the coupling beam 22 closer to a node of the mode of vibration in use reduces the strength of coupling when compared to positioning the coupling beam closer to anti-node of the mode of vibration, and so increases the scale factor of the accelerometer.

The coupling between the first and second resonant element can be achieved electrostatically instead of by a coupling beam. If a mechanical linkage is used, other shapes of beam are possible, as described with reference to FIG. 5 below.

In the embodiment of FIG. 1 third and fourth resonant elements are shown in dotted line. The third resonant element 17 is coupled to the first resonant element 16 by a mechanical linkage. The fourth resonant element 27 is coupled to the second resonant element 26 by a mechanical linkage. The third and fourth resonant elements are structurally identical to one another (and may be identical to the first and second resonant elements), and are coupled to the frame, but they are not coupled to either of the proof masses. The provision of further coupled resonant elements in this manner can enhance mode localisation and thereby improve the sensitivity of the measurement.

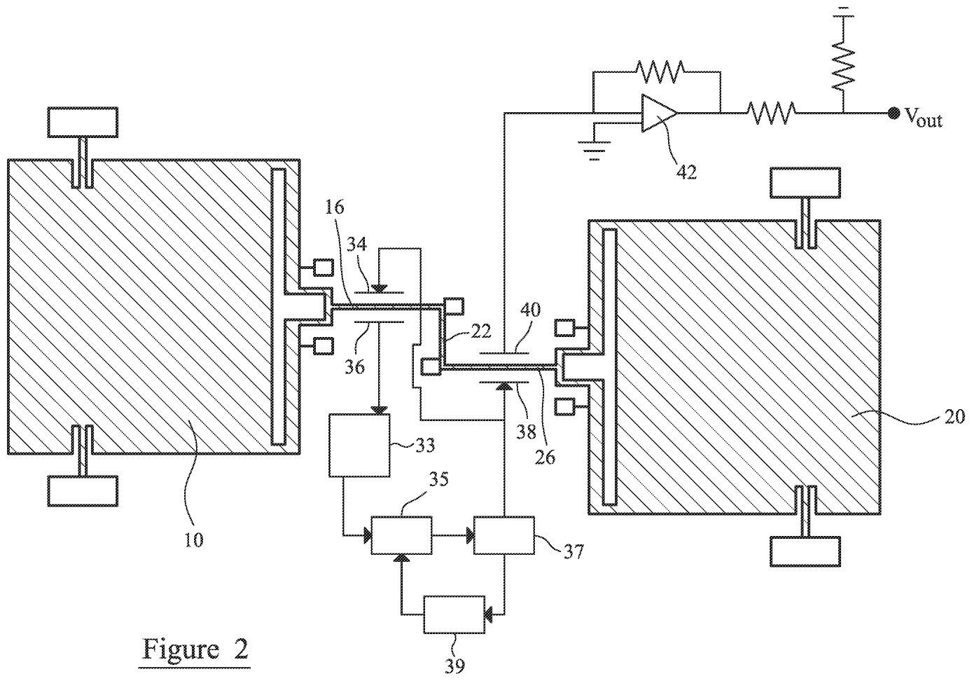

FIG. 2 illustrates an arrangement for driving the resonant elements of FIG. 1 and for providing an output measure of acceleration. In FIG. 2, third and fourth resonant elements are not provided.

The first and second resonant elements 16 and 26 are driven by an AC voltage signal from two separate drive electrodes 34 and 38. The same AC signal is applied to each drive electrode. The amplitude of oscillation of the first resonant element 16 is maintained at a constant level by sensing off electrode 36. The output from electrode 36 is fed into a control circuit, and the output of the control circuit fed back to drive electrodes 34 and 38. The first stage of the control circuit is a gain element 33 that provides a fairly large initial gain before feeding the signal into a variable gain amplifier (VGA) 35. The VGA 35 consists of an amplifier that adjusts its gain in accordance to a control signal (from an automatic gain control (AGC) circuit 39) and feeds the output to a buffer 37. The AGC 39 consists of a circuit that detects the output of the first stage gain element using a peak detector (that compares the peak amplitude of the output arising from the first gain stage with that of a reference signal) and accordingly controls the gain of the first stage gain element to maintain the output at a constant peak amplitude. The controlled output signal from the buffer 37 is, in turn, used to drive the resonant elements in the chosen mode of oscillation. The modal amplitudes of the second resonant element (at the resonant mode wherein the oscillations are sustained) is then read out from sense electrode 40.

Sensing of the amplitude of vibration may be implemented in several ways. In the embodiment shown in FIG. 2, the sensing of the amplitude of vibration of the first and second resonant elements may be achieved by measuring the motional current of the resonant elements as they oscillate from the sensing electrodes 36 and 40 respectively. Silicon also exhibits a strong piezoresistive effect, so the resistance of a silicon resonant element will change as it oscillates which may also be used as an alternative readout mechanism. Alternatively, the sensing means may comprise electrodes mounted adjacent to the first and second resonant elements to allow for capacitive sensing. Other possibilities for the sensing means include optical sensing of the oscillation of the first resonant element or even electro-magnetic transduction.

The output from the sense electrode 40 is fed into a trans-resistance amplifier circuit 42 to convert the current signal from electrode 40 into a voltage signal that may be used to directly calculate an amplified measure of the modal amplitude variation of the second resonant element 26, from which any induced changes in the stiffness of the first resonant element 1 may be evaluated. From the change in stiffness, acceleration can be determined.

If further coupled resonant elements are provided, the drive and sense arrangement can be extended, for instance by driving only the first and second resonant elements and sensing the response of all the resonant elements. Alternatively, all of the coupled resonant elements can be driven and sensed. Any number of coupled resonant elements can be used.

Instead of using feedback control to maintain the first resonant element at a constant amplitude, it is possible to read the amplitude of both the first and second resonant elements and determine the ratio of the amplitudes in order to provide a measure of acceleration. This drive and sensing scheme is described in WO2011/148137.

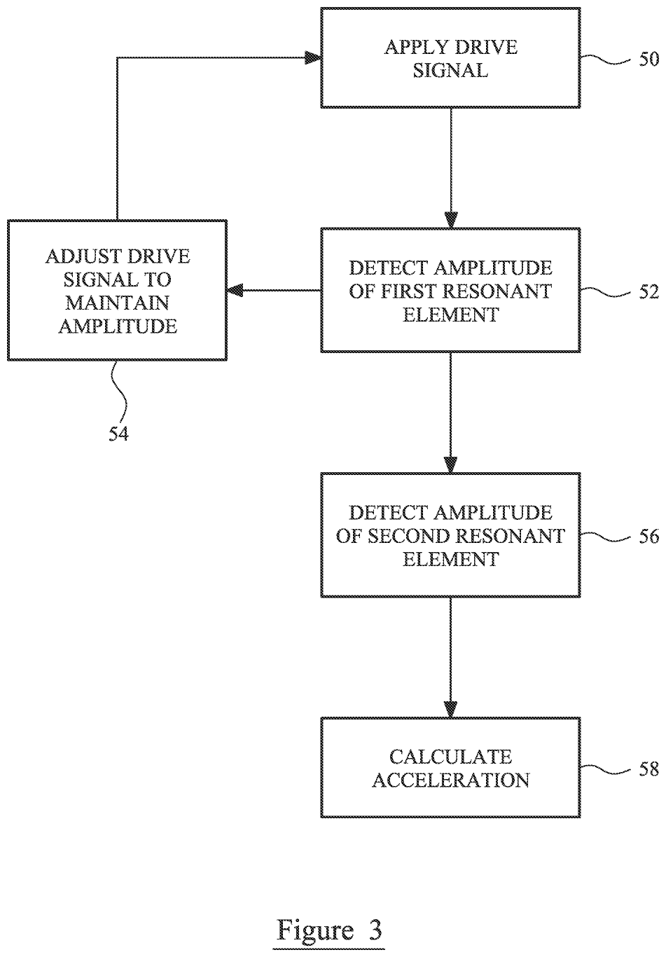

FIG. 3 is a flow diagram, illustrating the steps carried out in a method in accordance with the present invention using an accelerometer of the type described above with reference to FIGS. 1 and 2. In a first step, step 50, the resonant elements are caused to vibrate in a resonant mode using a drive signal. As described above the drive signal may comprise an AC voltage applied to the resonant elements and a DC biasing voltage applied to adjacent electrodes. In step 52, the amplitude of vibration of the first resonant element is detected. In step 54 the drive signal is adjusted to maintain the amplitude of the first resonant element at a constant level using a feedback loop. The amplitude of vibration of the second resonant element is detected in step 56 to provide a measure of the change in effective stiffness of the first resonant element, from which the acceleration or angular velocity of the proof mass along the axis of sensitivity can be determined in step 58.

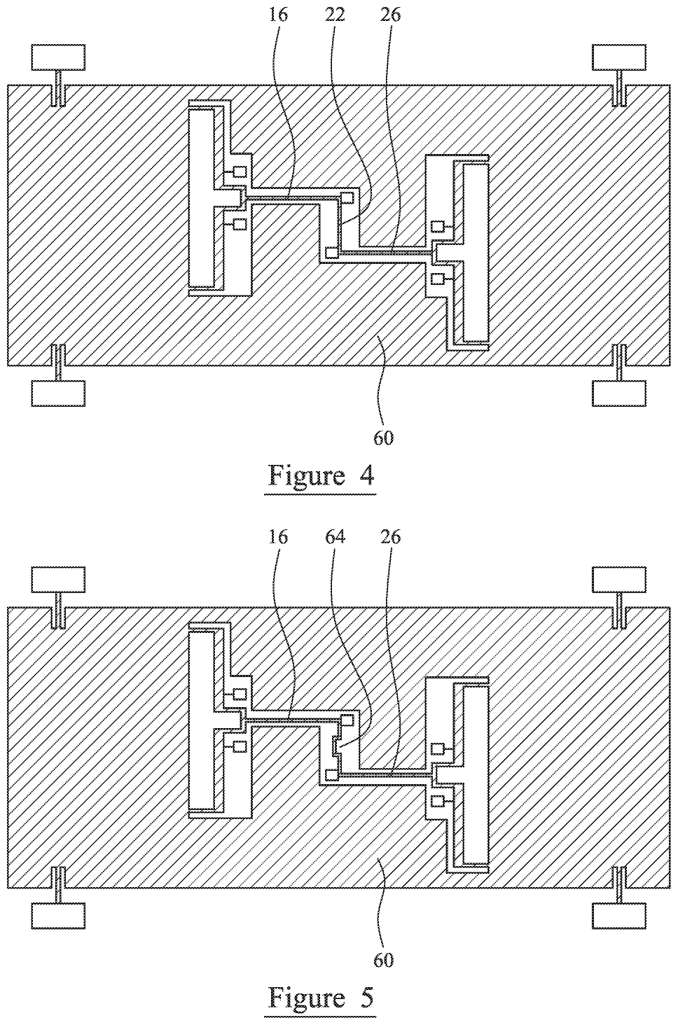

FIGS. 4, 5 and 6 illustrate further embodiments that are variations of the accelerometer of FIGS. 1 and 2.

In FIG. 4 a single proof mass 60 is used instead of separate first and second proof masses 10 and 20. The single proof mass is connected to both the first resonant element 16 and the second resonant element 26. In effect, the first and second proof masses of FIG. 1 are joined together and surround the first resonant element 16, second resonant element 26 and coupling beam 22. This arrangement operates in exactly the same way as the embodiment of FIG. 1, but allows the mass of the proof mass to be maximised for a given footprint of the accelerometer.

The embodiment of FIG. 5 is identical to the embodiment of FIG. 4 except for the form of the coupling beam between the first and second resonant elements. In the embodiment of FIG. 5 the coupling beam 22 is a serpentine shaped beam. The coupling strength provided by a serpentine shaped beam can be less sensitive to temperature fluctuations than a simple linear beam and therefore can result in better common mode rejection of noise due to temperature variations.

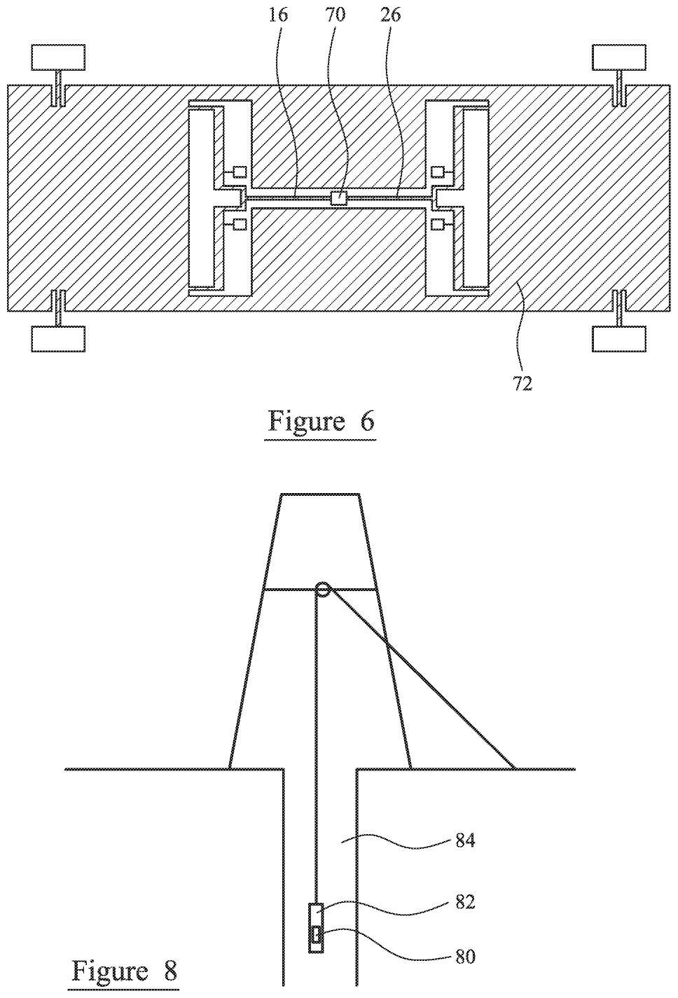

The embodiment of FIG. 6 is identical to the embodiment of FIG. 4 except for manner in which the coupling between the first and second resonant elements is provided. In the embodiment of FIG. 6, the first and second resonant elements 16, 26 are arranged coaxially along the sensitive axis of the accelerometer and coupling between them is provided by a non-ideal anchor 70. A separate coupling beam is not required. This arrangement has the advantage that the sensing axis of the two resonant elements are not offset from one another. It also has the advantage that impact of temperature fluctuations on a coupling beam are removed. However, it can be difficult to achieve a consistent level of coupling between the resonant elements from one device to the next in a manufacturing process.

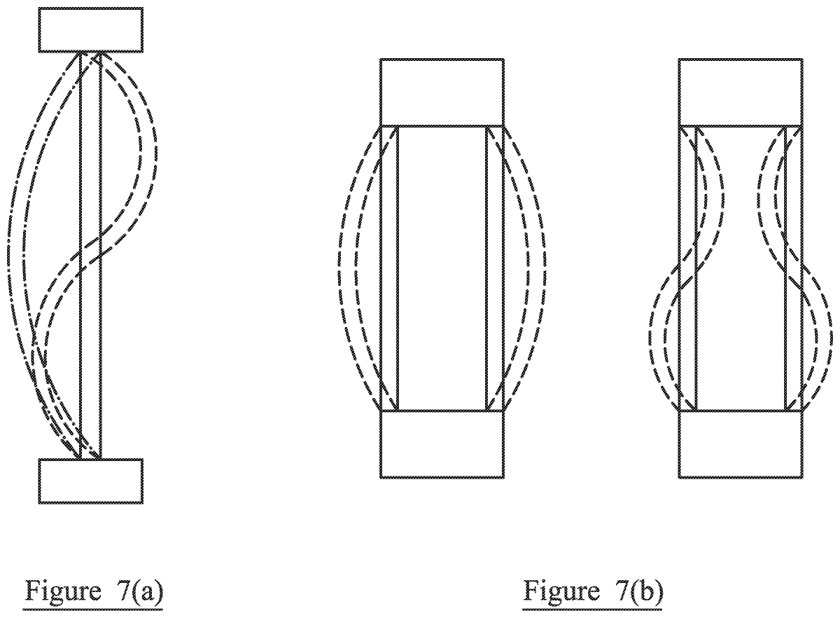

In the embodiments of FIGS. 1, 4 and 5, the first and second resonant elements 16, 26 may take the form of a simple clamped-clamped beam, as illustrated in FIG. 7a or may take the form of a double ended tuning fork (DETF) as shown in FIG. 7b. Different modal shapes for the two types of resonant element are illustrated in dotted line in FIG. 7.

In the embodiment of FIG. 6, in which coupling through the anchor 70 is required, it is advantageous to use a simple clamped-clamped beam, as illustrated in FIG. 7a. If DETF elements are employed, they will be operated in the in-phase mode preferentially to enable mechanical coupling between the resonant elements through the anchor.

An accelerometer as described can be used for many applications. One example is as a gravimeter. A gravimeter can be used for surveying in oil or gas extraction. FIG. 10 illustrates a gravimeter down a bore hole. Measurements of the gravity field down a borehole can provide information about the density of the surrounding layers and so information about the presence of oil or gas reserves and their size and location. This requires measurement of gravitational filed in three dimensions. A shown in FIG. 8, an accelerometer 80 in accordance with the invention is positioned within a borehole tool 82. The borehole tool is placed in the bore 84, suspended from a suitable structure on the surface. Gravimeters of this sort can be used in other applications, such as carbon storage monitoring, monitoring groundwater depletion, discovery of underwater aquifers, monitoring other processes underpinning the hydrological cycle, early-warning systems for earthquake-prone zones or for areas impacted by volcanic activity.

1. An accelerometer comprising:
a frame;
one or more proof masses suspended from the frame by one or more flexures and movable relative to the frame along a sensing axis;
a resonant element assembly, the resonant element assembly comprising a first resonant element and a second resonant element coupled to one another, the first resonant element connected between the one or more proof masses and the frame, the second resonant element connected between the one or more proof masses and the frame, such that movement of the one or more proof masses relative to the frame along the sensing axis results in one of the first and second resonant elements undergoing compression and the other of the first and second resonant elements undergoing tension; and
drive circuitry configured to drive the resonant element assembly into one or more resonant modes and a sensing circuit configured to determine a measure of acceleration based on changes in resonant behaviour of the first and second resonant elements.

2. An accelerometer according to claim 1, wherein the first and second resonant elements are substantially identical.

3. An accelerometer according to claim 1 or 2, wherein the one or more proof masses comprises a single proof mass and the first and second resonant elements are both coupled to the single proof mass.

4. An accelerometer according to claim 3, wherein the first and second resonant elements are surrounded by the single proof mass.

5. An accelerometer according to any one of the preceding claims wherein one or both of the first and second resonant elements is connected to the one or more proof masses through an force amplifying lever.

6. An accelerometer according to any one of the preceding claims wherein the first resonant element is coupled to the second resonant element by a mechanical coupling.

7. An accelerometer according to claim 6, wherein the first resonant element is connected to the frame at a first anchor and the second resonant element is connected to the frame at a second anchor, and wherein the mechanical coupling is positioned at or close to a nodal point of a mode of vibration of the resonant element assembly.

8. An accelerometer according to claim 6, wherein the mechanical coupling is a portion of the frame, the first and second resonant elements being connected to the frame at a common anchor.

9. An accelerometer according to claim 6 or 7, wherein the mechanical coupling comprises a serpentine beam.

10. An accelerometer according to any one of the preceding claims, wherein the first and second resonant elements are electrostatically coupled to one another.

11. An accelerometer according to any one of the preceding claims, comprising a third resonant element coupled to one or both of the first and second resonant elements.

12. An accelerometer according to claim 11, wherein the third resonant element has different mechanical properties to the first resonant element and the second resonant element.

13. An accelerometer according to claim 12, wherein the third resonant element has a different stiffness to the first resonant element and the second resonant element.

14. An accelerometer according to any one of the preceding claims, wherein the drive circuitry is configured to provide a parametric pumping signal to the resonant element assembly.

15. An accelerometer according to any one of the preceding claims, wherein the sensing circuitry is configured to provide an output based on the amplitudes of vibration of the first resonant element and the second resonant element.

16. A gravimeter comprising an accelerometer according to any one of the preceding claims.

17. A borehole tool comprising one or more accelerometers in accordance with claims 1 to 15.
